(19) United States
(12) Patent Application Publication
(10) Pub. No.: US 2011/0042722 A1
(43) Pub. Date: Feb. 24, 2011

(54) INTEGRATED CIRCUIT STRUCTURE AND MEMORY ARRAY

(75) Inventors: Shing Hwa Renn, Taipei City (TW); Shian Jyh Lin, Yonghe City (TW)

Correspondence Address: HAMRE, SCHUMANN, MUELLER & LARSON, P.C., P.O. BOX 2902, MINNEAPOLIS, MN, 55402-0902, US

(73) Assignee: NANYA TECHNOLOGY CORP., KUEISHAN (TW)

(21) Appl. No.: 12/545,739

(22) Filed: Aug. 21, 2009

(51) Int. Cl. H01L 27/105

(52) U.S. Cl. 257/208; 257/E29.166; 257/E27.081

(57) ABSTRACT

An integrated circuit structure includes a plurality of first doped regions disposed in a substrate in a matrix having odd columns and even columns each immediately adjacent to a corresponding one of the odd columns, a plurality of buried bit lines disposed in the substrate to electrically connect to the plurality of first doped regions of the same odd column in the matrix, and a plurality of surface bit lines disposed above an uppermost surface of the substrate, wherein each of the surface bit lines electrically connects to the first doped regions of the same even column in the matrix.

### BACKGROUND OF THE INVENTION

(A) Field of the Invention

The present invention relates to an integrated circuit structure and memory array, and more particularly, to an integrated circuit structure and memory array utilizing surface bit lines and buried bit lines in an alternating manner.

(B) Description of the Related Art

Memory is widely applied in the integrated circuit industry and plays an essential role in the electronic industry. As the industry develops, the demand for high-density memory increases and correlative industries research and develop high-density memory to satisfy the demand. Therefore, finding ways to maintain quality as device dimension is scaled down is a major challenge currently faced by the industry. For the storage of digital data, the capacitance of the memory is called a “bit” and the unit for data storage in a memory is called a “memory cell.” The memory cell is arranged in an array, consisting of columns and rows. A column and a row together represent a specific address. Memory cells in the same column or the same row are coupled by a common wiring line, which is called a word line. The vertical wiring line related to data transmittance is called a bit line. As the design rule for the integrated circuit device shrinks down to sub-50 nm scale, the bit line pitch for memory transistors or memory array face lithography limitations for line formation with equal line space, edge roughness, and shorts between adjacent bit lines. However, the new immersion lithography is the most common way to provide equal line space of bit lines for sub-60 nm generation memory devices. The next approach is to use EUV (Extreme Ultraviolet) with huge costs for better line patterning. However, advance lithography tools are usually very expensive. In addition, complex process controls, introduced to reduce yield loss, result in increased production cost. Thus, it is necessary to develop a novel cell design to solve the above-mentioned problems.

### SUMMARY OF THE INVENTION

One aspect of the present invention provides an integrated circuit structure and memory array utilizing surface bit lines and buried bit lines in an alternating manner, which can be fabricated by two lithographic processes so as to decrease precision demand on advanced lithographic techniques.

An integrated circuit structure according to this aspect of the present invention comprises a plurality of first doped regions disposed in a substrate in a matrix having odd columns and even columns each immediately adjacent to a corresponding one of the odd columns, a plurality of buried bit lines disposed in the substrate to electrically connect to the plurality of first doped regions of the same odd column in the matrix, and a plurality of surface bit lines disposed above an uppermost surface of the substrate, wherein each of the surface bit lines electrically connects to the first doped regions of the same even column in the matrix.

Another aspect of the present invention provides a memory array, comprising a substrate having an uppermost surface, a plurality of active areas disposed in the substrate in a matrix including a plurality of odd columns and even columns, a transistor disposed in each of the active areas, an isolation structure configured to electrically isolate the active areas from each other, a plurality of buried bit lines disposed within the isolation structure, and a plurality of surface bit lines disposed above the uppermost surface. Each transistor includes a first doped region, a second doped region, a carrier channel disposed between the first doped region and the second doped region, and a gate disposed on the carrier channel. Each of the buried bit lines electrically connects to the first doped regions of the same odd column in the matrix, and each of the surface bit lines electrically connects to the first doped regions of the same even column in the matrix.

The foregoing has outlined rather broadly the features of the present invention in order that the detailed description of the invention that follows may be better understood. Additional features of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives of the present invention will become apparent upon reading the following description and upon reference to the accompanying drawings in which:

FIG. 1 illustrates a layout of an integrated circuit structure according to one embodiment of the present invention;

FIG. 2 illustrates a close-up view along the cross-sectional line 1-1 in FIG. 1;

FIG. 3 illustrates a layout of an integrated circuit structure according to another embodiment of the present invention;

FIG. 4 illustrates a layout of a memory array according to one embodiment of the present invention;

FIG. 5 illustrates a close-up view along the cross-sectional line 2-2 in FIG. 4;

FIG. 6 illustrates a close-up view along the cross-sectional line 3-3 in FIG. 4; and

FIG. 7 illustrates a layout of a memory array according to another embodiment of the present invention.

### DETAILED DESCRIPTION OF THE INVENTION

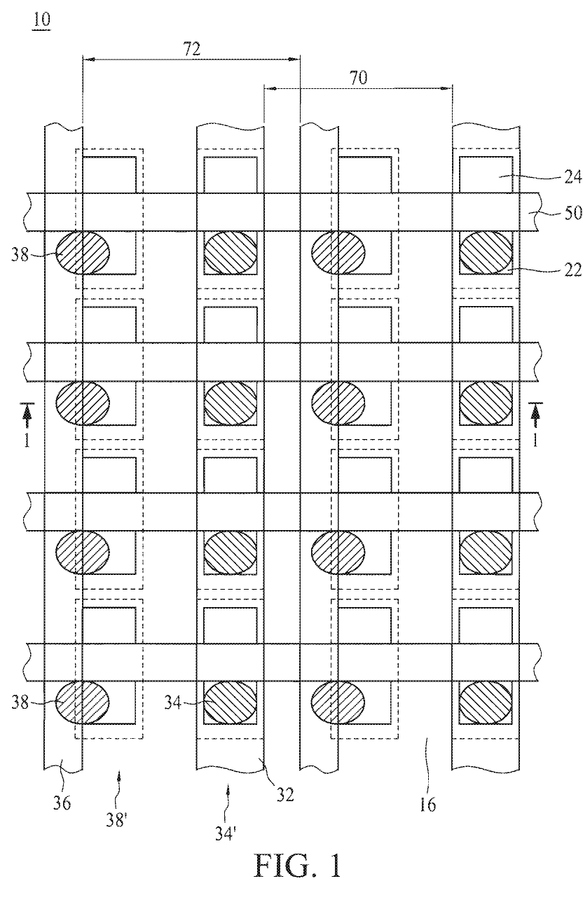

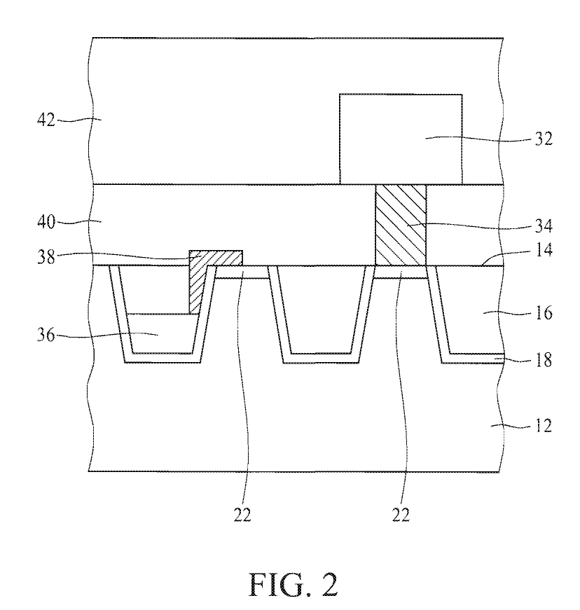

FIG. 1 illustrates a layout of an integrated circuit structure 10 according to one embodiment of the present invention, and FIG. 2 illustrates a close-up view along the cross-sectional line 1-1 in FIG. 1. The integrated circuit structure 10 comprises a plurality of first doped regions 22 and second doped regions 24 in a semiconductor substrate 12 such as a silicon wafer, a plurality of buried bit lines 36 disposed within the semiconductor substrate 12, and a plurality of surface bit lines 32 disposed above an uppermost surface 14 of the semiconductor substrate 12. The first doped regions 22 are arranged in a matrix including a plurality of odd columns 38′ and even columns 34′ each immediately adjacent to a corresponding one of the odd columns 38′. Each of the buried bit lines 36 electrically connects to the first doped regions 22 of the same odd column 38′ in the matrix via bit line contacts 38, and each of the surface bit lines 32 electrically connects the first doped region 22 of the same even column 34′ in the matrix via bit line contacts 34.

In one embodiment of the present invention, each of the surface bit lines 32 has a width different from that of each of the buried bit lines 36; for example, the width of the surface bit line 32 is greater than the width of the buried bit line 32 in FIG. 1. In a further embodiment of the present invention, the surface bit line 32 extends in a linear pattern, and the buried bit line 36 extends in a linear pattern. The integrated circuit structure 10 further includes a plurality of word lines 50 substantially perpendicular to the buried bit lines 36 and the surface bit lines 32 in one embodiment of the present invention. Each first doped region 22 is disposed at one side of each word line 50 and each second doped region 24 is disposed at the other side of each word line 50.

Referring to FIG. 2, the buried bit line 36 is disposed in an isolation structure 16 including a plurality of shallow trench isolations filled with dielectric material in the semiconductor substrate 12, and a dielectric layer 18 electrically separates the buried bit line 36 from the semiconductor substrate 12. The surface bit lines 32 and the bit line contacts 34 are electrically separated from the other conductive members of the integrated circuit structure 10 by dielectric layers 40, 42.

With designs that do not have separated buried bit lines and surface bit lines at different levels, the bit lines are disposed at the same level with equal line space, requiring advanced lithographic technique such as the liquid immersion lithographic technique. By contrast, one embodiment of the present invention uses a design utilizing buried bit lines 36 and surface bit lines 32 at different levels of the integrated circuit structure 10, i.e., the buried bit lines 36 and the surface bit lines 32 are fabricated separately by different lithographic processes, and the spacing between the buried bit lines 36 and the spacing between the surface bit lines 32 can be significantly greater without incurring problems. Preferably, the buried bit lines 36 and the surface bit lines 32 are arranged in an alternating manner; therefore, the surface bit lines 32 are separated by a lateral space 70, and the buried bit lines 36 are separated by a lateral space 72. Consequently, by using the design of the buried bit lines 36 and the surface bit lines 32 at different levels of the integrated circuit structure 10, the use of expensive, next-generation lithographic techniques such as liquid immersion lithographic technique can be postponed to later designs.

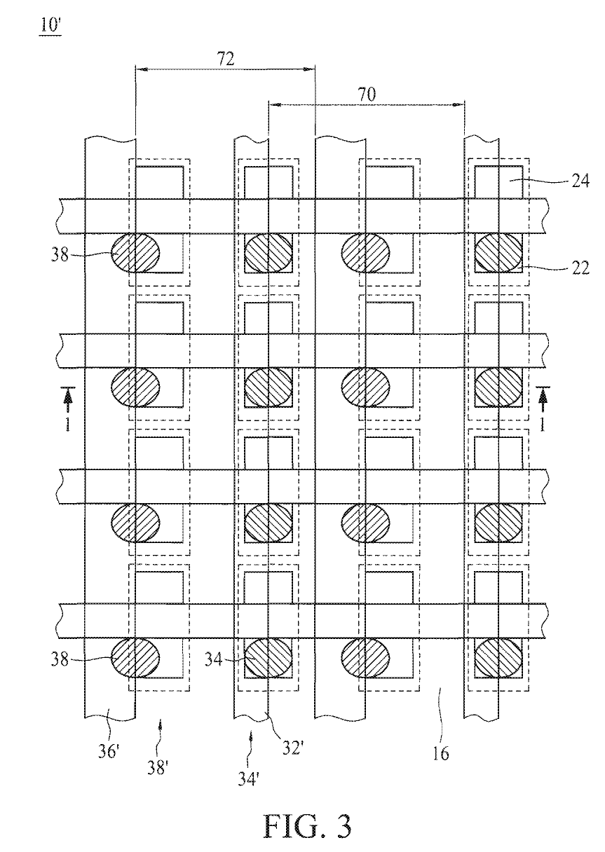

FIG. 3 illustrates a layout of an integrated circuit structure 10′ according to another embodiment of the present invention. In FIG. 1, the width of the surface bit line 32 is designed to be greater than the width of the buried bit line 32 in one embodiment of the present invention. By contrast, the width of the surface bit line 32 is designed to be less than the width of the buried bit line 36 in another embodiment of the present invention, as shown in FIG. 3.

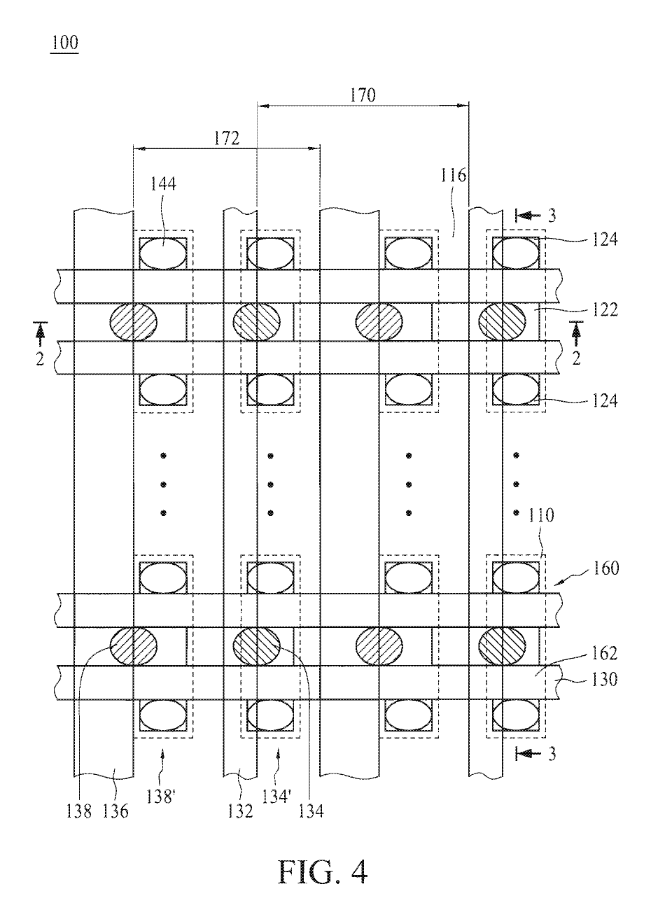

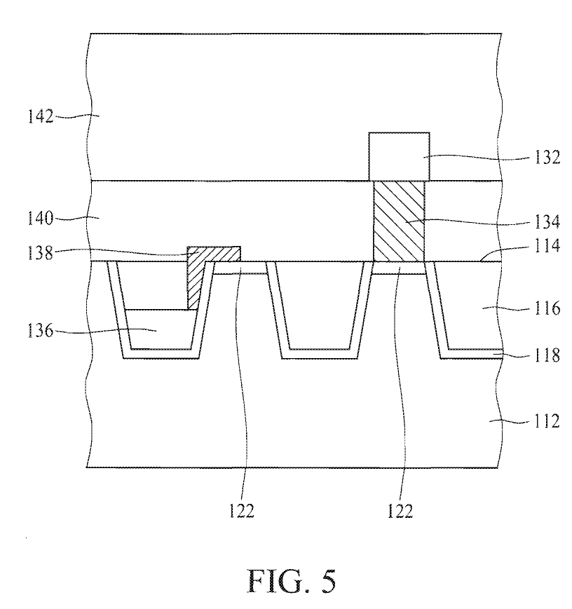

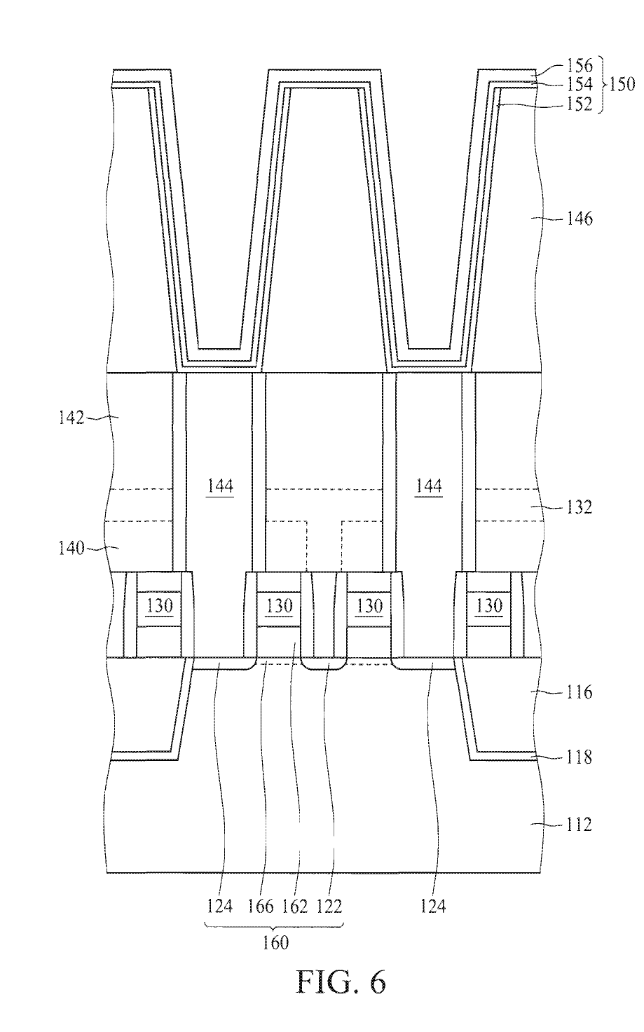

FIG. 4 illustrates a layout of a memory array 100 according to one embodiment of the present invention; FIG. 5 illustrates a close-up view along the cross-sectional line 2-2 in FIG. 4; and FIG. 6 illustrates a close-up view along the cross-sectional line 3-3 in FIG. 4. The memory array 100 comprises a semiconductor substrate 112, a plurality of active areas 110 disposed in the semiconductor substrate 11 2, a transistor 160 disposed in each active area 110, a word line 130 coupled to a gate 162 of the transistor 160, an isolation structure 116 including a plurality of shallow trench isolations configured to electrically isolate the active areas 110 from each other, a plurality of buried bit lines 136 disposed within the semiconductor substrate 112, and a plurality of surface bit lines 132 disposed on the semiconductor substrate 112. The buried bit lines 136 are disposed within the isolation structure 11 6 and electrically isolated from the semiconductor substrate 112 by a dielectric layer 118, as shown in FIG. 5.

Referring to FIG. 6, each transistor 160 includes a first doped region 122, a second doped region 124, a carrier channel 166 disposed between the first doped region 122 and the second doped region 124, and a gate 162 disposed on the carrier channel 166. In one embodiment of the present invention, the memory array 100 includes a plurality of capacitors 150 electrically connected to the second doped regions 124 via capacitor contacts 144. The capacitors 150 are electrically isolated from each other by a dielectric layer 146. In one embodiment of the present invention, each of the capacitors 150 includes a bottom electrode 152 electrically connected to the capacitor contact 144, an upper electrode 156, and a dielectric layer 154 sandwiched between the bottom electrode 152 and the upper electrode 156.

Referring back to FIG. 4, the active areas 110 are disposed in the semiconductor substrate 112 in a matrix including a plurality of odd columns 138′ and even columns 134′. Each of the buried bit lines 136 electrically connects to the first doped regions 122 of the same odd column 138′ in the matrix via bit line contacts 138. The surface bit lines 132 are disposed above an uppermost surface 114 of the semiconductor substrate 112, and each of the surface bit lines 132 electrically connects to the first doped regions 122 of the same even column 134′ in the matrix via bit line contacts 134. The surface bit lines 132 and the bit line contacts 134 are electrically separated from the other conductive member of the memory array 100 by dielectric layers 140, 142. In one embodiment of the present invention, each of the surface bit lines 132 has a width different from that of each of the buried bit lines 136; for example, the width of the buried bit line 136 is greater than the width of the surface bit line 132 in FIG. 4. In a further embodiment of the present invention, the surface bit line 132 extends in a linear pattern, and the buried bit line 136 extends in a linear pattern.

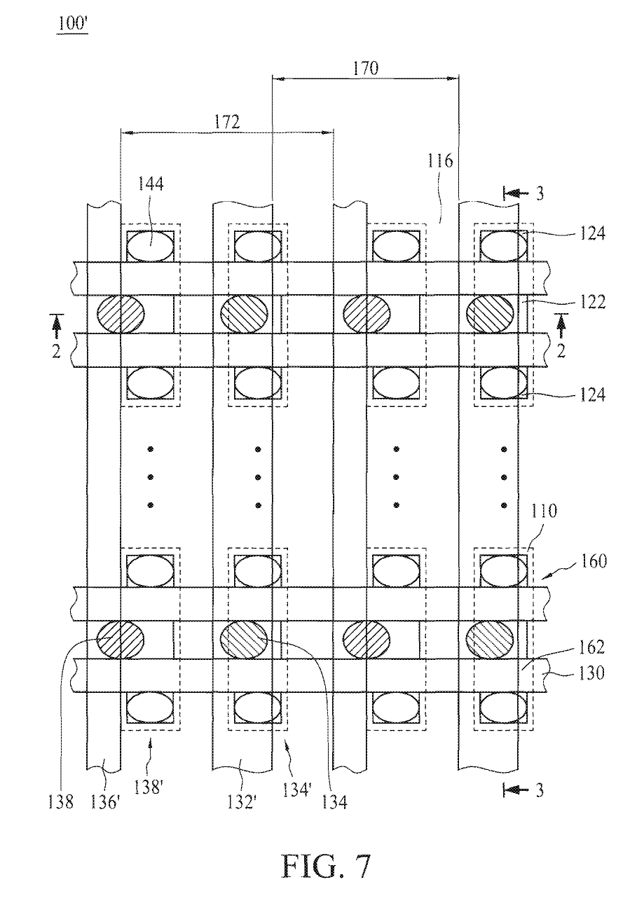

FIG. 7 illustrates a layout of a memory array 100′ according to another embodiment of the present invention. In FIG. 4, the width of the buried bit line 136 is designed to be greater than the width of the surface bit line 132 in one embodiment of the present invention. By contrast, the width of the buried bit line 136′ is designed to be less than the width of the surface bit line 132′ in another embodiment of the present invention, as shown in FIG. 7.

With designs that do not have separated buried bit lines and surface bit lines at different levels, the bit lines are disposed at the same level with equal line space, requiring advanced lithographic technique such as the liquid immersion lithographic technique. By contrast, one embodiment of the Is present invention uses a design utilizing buried bit lines 136 and surface bit lines 132 at different levels of the memory array 100, i.e., the buried bit lines 136 and the surface bit lines 132 are fabricated separately by different lithographic processes, and the spacing between the buried bit lines 136 and the spacing between the surface bit lines 132 can be significantly greater without incurring problems. Preferably, the buried bit lines 136 and the surface bit lines 132 are arranged in an alternating manner; therefore, the surface bit lines 132 are separated by a lateral space 170, and the buried bit lines 136 are separated by a lateral space 172. Consequently, by using the design of the buried bit lines 136 and the surface bit lines 132 at different levels of the memory array 100, the use of expensive next-generation lithographic techniques such as liquid immersion lithographic technique can be postponed to later designs.

Although the present invention and its objectives have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit structure, comprising:
a plurality of first doped regions disposed in a substrate in a matrix having odd columns and even columns each immediately adjacent to a corresponding one of the odd columns;
a plurality of buried bit lines disposed in the substrate to electrically connect to the plurality of first doped regions of the same odd column in the matrix; and
a plurality of surface bit lines disposed above an uppermost surface of the substrate, wherein each of the surface bit lines electrically connects to the first doped regions of the same even column in the matrix.

2. The integrated circuit structure of claim 1, wherein each of the surface bit lines has a width different from that of each of the buried bit lines.

3. The integrated circuit structure of claim 1, wherein each of the surface bit lines has a width greater than that of each of the buried bit lines.

4. The integrated circuit structure of claim 1, wherein each of the surface bit lines has a width less than that of each of the buried bit lines.

5. The integrated circuit structure of claim 1, wherein the buried bit lines are disposed in an isolation structure in the semiconductor substrate.

6. The integrated circuit structure of claim 5, wherein the isolation structure comprises a plurality of shallow trench isolations.

7. The integrated circuit structure of claim 1, wherein the surface bit lines extend in a linear pattern.

8. The integrated circuit structure of claim 1, wherein the buried bit lines extend in a linear pattern.

9. The integrated circuit structure of claim 1, wherein the buried bit lines and the surface bit lines are arranged in an alternating manner.

10. The integrated circuit structure of claim 1, further comprising:
a plurality of word lines substantially perpendicular to the bit lines, wherein each first doped region is disposed at one side of each word line; and
a plurality of second doped regions disposed in the substrate, wherein each second doped region is disposed at the other side of each word line.

11. A memory array, comprising:
a substrate having an uppermost surface;
a plurality of active areas disposed in the substrate in a matrix including a plurality of odd columns and even columns;
a transistor disposed in each active area, wherein each transistor includes a first doped region, a second doped region, a carrier channel disposed between the first doped region and the second doped region a gate disposed on the carrier channel;
an isolation structure configured to electrically isolate the active areas from each other;
a plurality of buried bit lines disposed in the isolation structure, wherein each of the buried bit lines electrically connects to the first doped regions of the same odd column in the matrix; and
a plurality of surface bit lines disposed above the uppermost surface, wherein each of the surface bit lines electrically connects to the first doped regions of the same even column in the matrix.

12. The memory array of claim 11, wherein each of the surface bit lines has a width different from that of each of the buried bit lines.

13. The memory array of claim 11, wherein each of the surface bit lines has a width greater than that of each of the buried bit lines.

14. The memory array of claim 11, wherein each of the surface bit lines has a width less than that of each of the buried bit lines.

15. The memory array of claim 11, wherein the surface bit lines extend in a linear pattern.

16. The memory array of claim 11, wherein the buried bit lines extend in a linear pattern.

17. The memory array of claim 11, wherein the second doped region is connected to a capacitor.

18. The memory array of claim 11, wherein the isolation structure comprises a plurality of shallow trench isolations.

19. The memory array of claim 11, wherein the buried bit lines and the surface bit lines are arranged in an alternating manner.
